(19) United States
(12) Patent Application Publication
(10) Pub. No.: US 2015/0275373 A1
(43) Pub. Date: Oct. 1, 2015

(54) DEVICE AND METHOD FOR COATING SUBSTRATES

(71) Applicant: OSRAM GMBH, München (DE)

(72) Inventors: Klaus-Dieter Bauer, Landau (DE); Frank Vollkommer, Gauting (DE); Juergen Bauer, Wielenbach (DE); Philipp Erhard, Mering (DE)

(73) Assignee: OSRAM GmbH, Munich (DE)

(21) Appl. No.: 14/430,970

(22) PCT Filed: Sep. 25, 2013
(86) PCT No.: PCT/EP2013/070012

§ 371 Date: Mar. 25, 2015

(30) Foreign Application Priority Data
Sep. 28, 2012 (DE) 10 2012 109 251.6

(51) Int. Cl. C23C 16/54; C23C 16/44; C23C 16/455

(52) U.S. Cl. CPC C23C 16/545; C23C 16/45536; C23C 16/45544; C23C 16/4401

(57) ABSTRACT

Various embodiments may relate to a device for coating substrates. The device includes a reaction space element configured to arrange substrate portions of one or more substrates as opposite outer walls of a reaction space, and a material feed element configured to introduce one or more materials into the reaction space for coating surfaces of the substrate portions which are opposite one another in the reaction space. Various embodiments further relate to a method for coating substrates.

### RELATED APPLICATIONS

The present application is a national stage entry according to 35 U.S.C. §371 of PCT application No.: PCT/EP2013/070012 filed on Sep. 25, 2013, which claims priority from German application No.: 10 2012 109 251.6 filed on Sep. 28, 2012, and is incorporated herein by reference in its entirety.

### TECHNICAL FIELD

Various embodiments may relate to a device and a method for coating substrates, in particular flexible substrates, for example by atomic layer deposition (ALD) or molecular layer deposition (MLD) processes.

### BACKGROUND

A concept used in ALD/MLD development is based on what are known as cross-flow or travelling-wave reactors. Here, a first starting product (“precursor”), typically in an inert carrier gas, then only the inert carrier gas, and then a second precursor and then once more pure inert carrier gas are led through the reactor, for example one after another, and therefore over the surface of a substrate fitted within the reactor. During such a cycle, a monolayer of the desired molecule or atomic union formed is deposited on the substrate but also on the reactor walls. This sequence is repeated until the desired number of atomic or molecular layers on the substrate is reached. This type of ALD is normally designated as “sequential ALD”.

An alternative concept is what is known as “spatial ALD”. The structure of the spatial ALD systems normally includes one or more large-area coating heads and is relatively complicated as compared with “sequential ALD”. A particular challenge in the case of these systems is reliably to avoid touching the substrates with the coating head.

### SUMMARY

Various embodiments provide a novel type of device and a novel type of method for coating substrates.

According to various embodiments, a device for coating substrates is provided, including a reaction space element and a material feed element.

In various embodiments, a device for coating substrates is provided, said device including: a reaction space element configured to arrange substrate portions of one or more substrates as mutually opposite outer walls of a reaction space; and a material feed element configured to introduce one or more materials into the reaction space for coating surfaces of the substrate portions which are opposite one another in the reaction space.

In one refinement, the reaction space element may be configured for the continuous or cyclic movement of the substrate portions.

In one refinement, the reaction space element may include at least two rolls, wherein the reaction space is arranged between the two rolls.

In one refinement, the reaction space element may include at least two pairs of rolls, wherein the reaction space is arranged between two pairs of rolls.

In one refinement, the material feed element may be arranged laterally along the reaction space.

In one refinement, the reaction space element may include a frame element, wherein the reaction space is arranged within the frame element.

In one refinement, the material feed element may be arranged on one side of the frame element.

In one refinement, the material feed element may form one side of the frame element.

In one refinement, the device may have a material removal element which is configured to extract the one or more materials out of the reaction space by vacuum.

In one refinement, the reaction space element may include one or more guide elements formed on the material feed element.

In one refinement, the device may have one or more electrodes, which are configured to generate a plasma in the reaction space.

In one refinement, the device may have a spacer element which is configured to set a distance between the substrate portions in the area of the reaction space.

In one refinement, the spacer element may include a vacuum element.

In one refinement, the spacer element may include at least two vacuum elements arranged on opposite sides of the substrate portions.

In one refinement, the device may have a plurality or a multiplicity of reaction space elements.

In one refinement, the device may have a plurality or a multiplicity of material feed elements.

In various embodiments, a method for coating substrates is provided, including: arranging substrate portions of one or more substrates as opposite outer walls of a reaction space; and introducing one or more materials into the reaction space for coating surfaces of the substrate portions which are opposite one another in the reaction space.

In one refinement, the method may include a continuous or cyclic movement of the substrate portions.

In one refinement, the method may include extracting the one or more materials out of the reaction space by vacuum.

In one refinement, the method may include generating a plasma in the reaction space.

In one refinement, the method may include setting a distance between the substrate portions in the area of the reaction space.

In one refinement, the method may also include one or more processes from a group including heating, exposing, vibrating, laminating and structuring the substrate portions.

At least some embodiments may advantageously ensure that an economical method for producing thin layers, for example on flexible substrates, by ALD or MLD processes with high material utilization and short process times is made possible.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a schematic representation of a perspective plan view of an embodiment of a device for coating substrates,

FIG. 2 shows a schematic representation of a perspective plan view of a further embodiment of a device for coating substrates,

FIG. 3 shows a schematic representation of a perspective plan view of a further embodiment of a device for coating substrates,

FIG. 4 shows a schematic representation of a perspective plan view of a further embodiment of a device for coating substrates,

FIG. 5 shows a schematic representation of a side view of a further embodiment of a device for coating substrates,

FIG. 6 shows a schematic representation of a perspective plan view of a further embodiment of a device for coating substrates, and

FIG. 7 shows a flow chart of an embodiment of a method for coating substrates.

### DETAILED DESCRIPTION

The following detailed description refers to the accompanying drawing that show, by way of illustration, specific details and embodiments in which the disclosure may be practiced.

In an embodiment of a device for coating substrates, the reaction space can be formed virtually completely from the substrates to be treated, for example portions of film unwound from rolls. The portions of film can be pressed onto each other, for example by respective pairs of rolls, on mutually opposite sides of the reaction space, so that a seal is achieved there in each case. However, the sealing can also be carried out in another way, e.g. with respective individual rolls on the opposite sides of the reaction space or e.g. by a frame between the films.

In an embodiment, a nozzle (e.g. having a slot or having a plurality of individual openings) can be arranged on one side of the reaction space delimited between the portions of film, through which nozzle the various process gases can be let in. On the opposite side, a similar nozzle can optionally be installed for extraction by vacuum.

In embodiments, the reaction space may advantageously be kept small by the distance between the films being, for example, only a few 10 μm. In some embodiments, the films may also touch from time to time during the process sequence, for example when gas pulses move through between the portions of film/substrates “in the manner of rolls”.

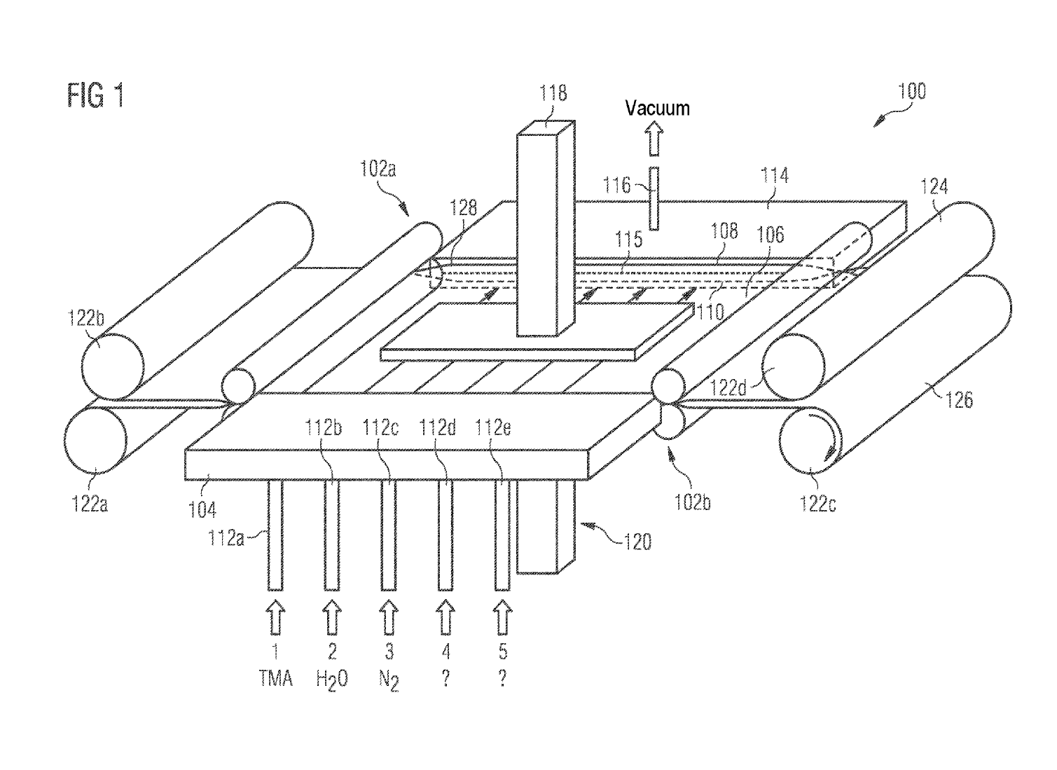

The embodiment shown in FIG. 1 of a device 100 for coating substrates includes a reaction space element, for example in the form of two pairs of rolls 102a, 102b, and a material feed element, for example in the form of a nozzle 104. The nozzle 104 has a slot directed into a reaction space 106 between mutually opposite substrate portions 108, 110. Various feed lines, e.g. 112a to 112e, are coupled to the nozzle 104, in order to introduce one or more materials, for example one or more precursors and one or more carrier gases for coating the substrates, into the reaction space 106.

By the pairs of rolls 102a, 102b, the substrate portions 108, 110 may be arranged as mutually opposite outer walls of the reaction space 106. Motorized rollers 122a to 122d guide films 124, 126, each at an angle, to and from the pairs of rolls 102a, 102b. The pairs of rolls 102a, 102b may advantageously press the films 124, 126 against each other in order to seal off the reaction space 106.

In this embodiment, the device 100 may include a material removal element, for example in the form of a second nozzle 114. The second nozzle 114 has a slot 115 directed toward the reaction space 106 in order to extract the materials by vacuum. A vacuum line 116 leading to a vacuum pump (not shown) is coupled to the second nozzle 114 for this purpose.

In this embodiment, the device 100 may additionally include a spacer element in the form of one or more vacuum elements, here two vacuum elements 118, 120 arranged on mutually opposite sides of the substrate portions 108, 110. The vacuum elements 118, 120 are each coupled to the substrate portions 108, 110 in order to set a selected distance between the substrate portions 108, 110 in the area of the reaction space 106.

In this embodiment, the reaction space element may further include guide elements formed on the nozzle 104 and/or the second nozzle 114, for example in the form of edges or inclined surfaces 128 for the substrate portions 108, 110. Optionally, the edges or inclined surfaces 128 may also be configured to form seals of the reaction space 106.

In another embodiment, use may be made of only one vacuum element, for example the vacuum element 118. In such embodiments, it is possible to prevent the upper and lower substrate portions 108, 110 from touching each other, since one vacuum element on the upper substrate portion 108 can be sufficient to compensate for the sagging of the latter. As a result, in such embodiments the lower side of the device 100 may still be free for other elements, for example an IR heater.

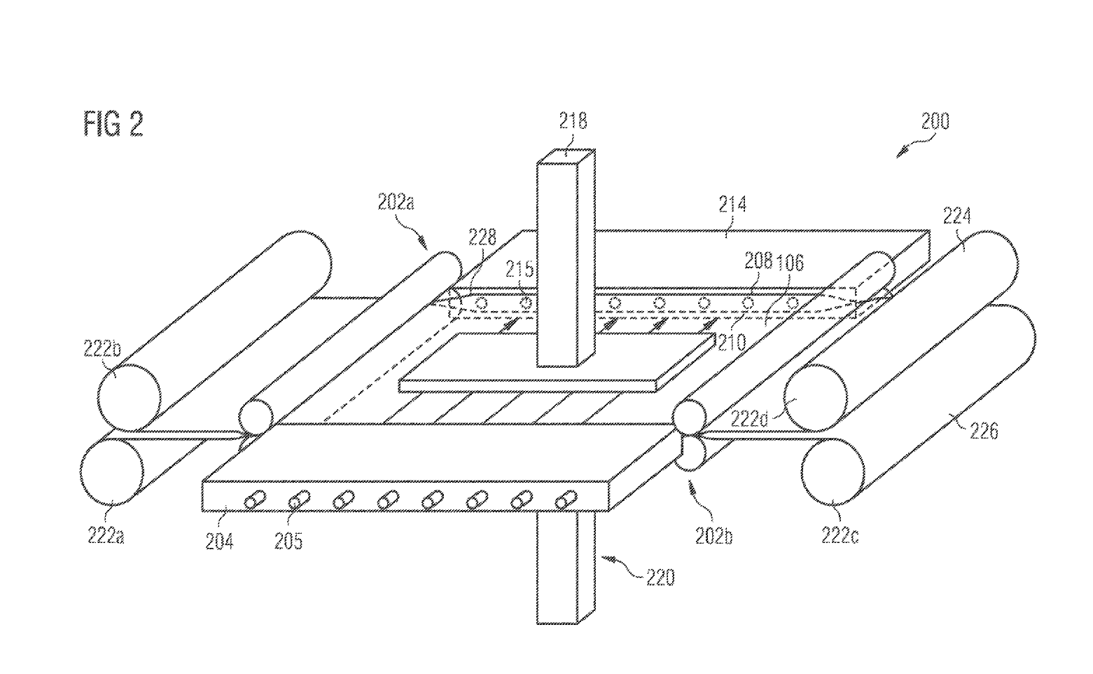

The embodiment shown in FIG. 2 of a device 200 for coating substrates includes a reaction space element, for example in the form of two pairs of rolls 202a, 202b, and a material feed element, for example in the form of a nozzle 204. The nozzle 204 has a plurality of individual conduits, e.g. conduits 205, to a reaction space 206 between mutually opposite substrate portions 208, 210. Various sources (not shown) are coupled to the conduits, for example conduits 205, either respectively to all or respectively to one or more selected ones, in order to introduce one or more materials, for example one or more precursors and one or more carrier gases for coating the substrates, into the reaction space 206.

By the pairs of rolls 202a, 202b, the substrate portions 208, 210 may be arranged as mutually opposite outer walls of the reaction space 206. Motorized rollers 222a to 222d guide films 224, 226, each at an angle, to and from the pairs of rolls 202a, 202b. The pairs of rolls 202a, 202b may advantageously press the films 224, 226 against each other in order to seal off the reaction space 206.

In this embodiment, the device 200 may include a material removal element, for example in the form of a second nozzle 214. The second nozzle 214 has a plurality of individual conduits, e.g. conduits 215, for extracting the materials by vacuum. The fact that the material removal element in diverse embodiments is constructed in exactly the same way as the material feed element means that the material removal element can advantageously also be used as a material feed element and vice versa, i.e. the reaction space does not always need to be filled or emptied from the same side, instead the same may, for example, be carried out alternately from one side to the other or else simultaneously from both sides. As a result, for example, advantages in the homogeneity of the coating can be achieved (for example avoiding gradients). In addition, in some embodiments it is possible to implement a process in which both elements are simultaneously firstly feed and then removal elements, that is to say it is possible for filling to be carried out from both sides and then for pumping away to be carried out from both sides etc.

In this embodiment, the device 200 may additionally include a spacer element in the form of two vacuum elements 218, 220 arranged on mutually opposite sides of the substrate portions 208, 210. The vacuum elements 218, 220 are each coupled to the substrate portions 208, 210, in order to set a selected distance between the substrate portions 208, 210 in the area of the reaction space 206.

In this embodiment, the reaction space element may also include guide elements formed on the nozzle 204 and/or the second nozzle 214, for example in the form of edges or inclined surfaces 228 for the substrate portions 208, 210. Optionally, the edges or inclined surfaces 228 may also be configured to seal off the reaction space 206.

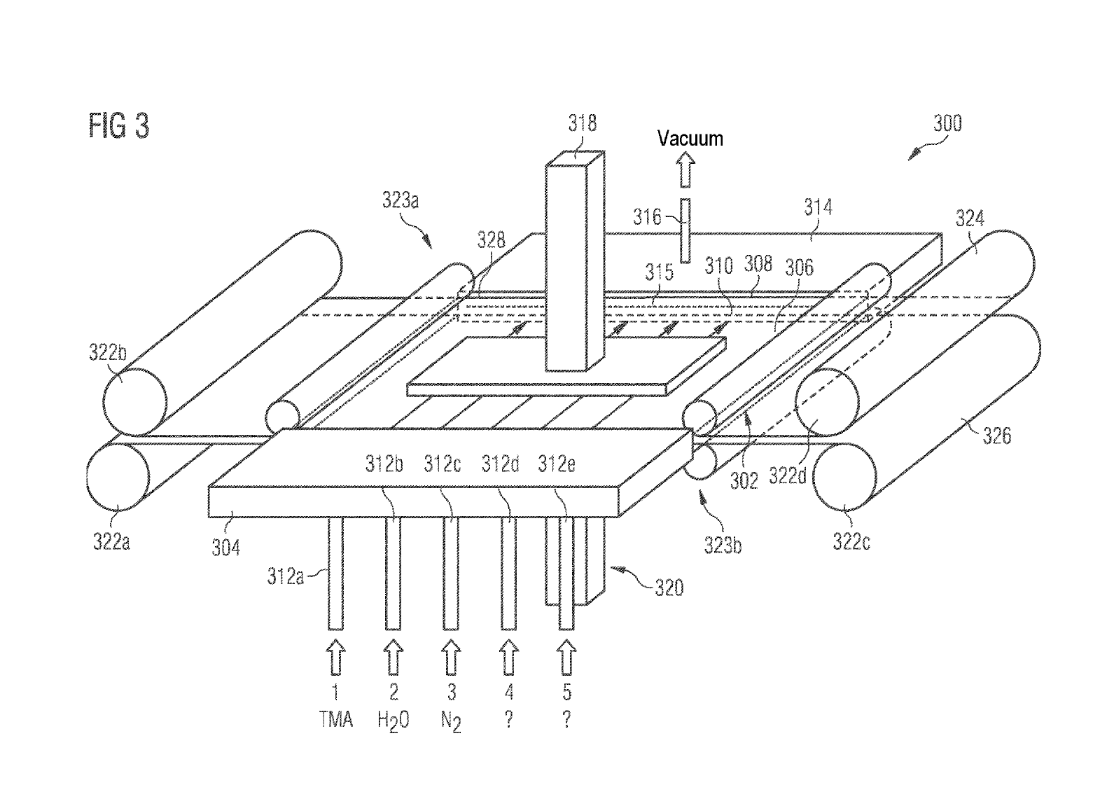

The embodiment shown in FIG. 3 of a device 300 for coating substrates includes a reaction space element, for example in the form of a frame 302, which is arranged between two opposite substrate portions 308, 310. A material feed element, for example in the form of a nozzle 304, forms one side of the frame 302.

By the frame 302, the substrate portions 308, 310 may be arranged as mutually opposite outer walls of the reaction space 306. Motorized rollers 322a to 322d guide films 324, 326, each at an angle, to and from pairs of rolls 323a, 323b. The pairs of rolls 323a, 323b can advantageously press the films 324, 326 onto the frame 302 in order to seal off the reaction space 306.

A reaction space 306 is formed within the frame 302 and between the opposite substrate portions 308, 310. The nozzle 304 has a slot directed into the reaction space 306. Various feed lines, e.g. 312a to 312e, are coupled to the nozzle 304 in order to introduce one or more materials, for example one or more precursors and one or more carrier gases for coating the substrates, into the reaction space 306.

In this embodiment, the device 300 may include a material removal element, for example in the form of a second nozzle 314. The second nozzle 314 has a slot 315 directed toward the reaction space 306 for extracting the materials by vacuum. A vacuum line 316 leading to a vacuum pump (not shown) is coupled to the second nozzle 314 for this purpose.

In this embodiment, the device 300 may additionally include a spacer element in the form of two vacuum elements 318, 320 arranged on mutually opposite sides of the substrate portions 308, 310. The vacuum elements 318, 320 are each coupled to the substrate portions 308, 310 in order to set a selected distance between the substrate portions 308, 310 in the area of the reaction space 306.

In this embodiment, the reaction space element may also include guide elements formed on the nozzle 304 and/or the second nozzle 314, e.g. in the form of edges or inclined surfaces 328 for the substrate portions 308, 310.

Optionally, the edges or inclined surfaces 328 may also be configured to seal off the reaction space 306.

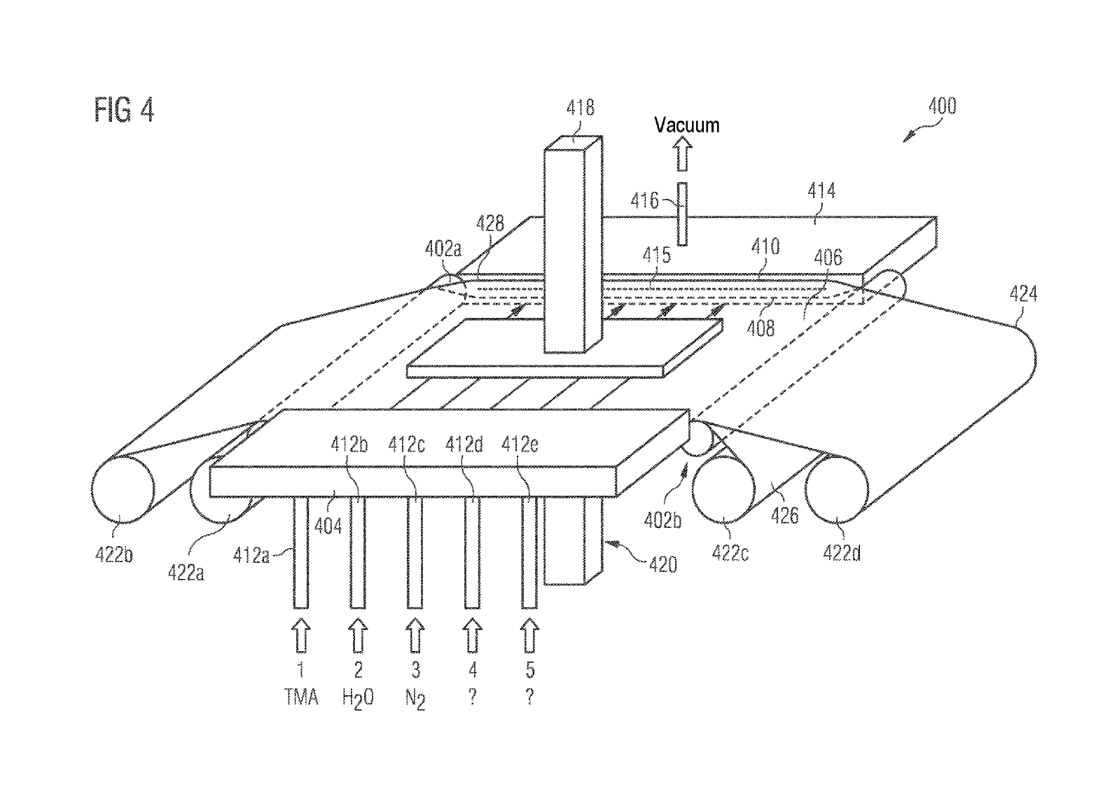

The embodiment shown in FIG. 4 of a device 400 for coating substrates includes a reaction space element, for example in the form of two rolls 402a, 402b, and a material feed element, for example in the form of a nozzle 404. The nozzle 404 has a slot directed into a reaction space 406 between mutually opposite substrate portions 408, 410. Various feed lines, e.g. 412a to 412e, are coupled to the nozzle 404 in order to introduce one or more materials, for example one or more precursors and one or more carrier gases for coating the substrates, into the reaction space 406.

By the rolls 402a, 402b, the substrate portions 408, 410 of a plurality of substrates can be arranged as mutually opposite outer walls of the reaction space 406. Motorized rollers 422a to 422d guide films 424, 426, each at an angle, to and from the rolls 402a, 402b. The films 424, 426 can thus advantageously be pressed onto the rolls 402a, 402b in order to seal off the reaction space 406.

In this embodiment, the device 400 may include a material removal element in the form of a second nozzle 414. The second nozzle 414 has a slot 415 directed toward the reaction space 406 to extract the materials by vacuum. A vacuum line 416 leading to a vacuum pump (not shown) is coupled to the second nozzle 414 for this purpose.

In this embodiment, the device 400 may additionally include a spacer element in the form of two vacuum elements 418, 420 arranged on mutually opposite sides of the substrate portions 408, 410. The vacuum elements 418, 420 are each coupled to the substrate portions 408, 410, in order to set a selected distance between the substrate portions 408, 410 in the area of the reaction space 406.

In this embodiment, the reaction space element may also include guide elements formed on the nozzle 404 and/or the second nozzle 414, e.g. in the form of edges or inclined surfaces 428 for the substrate portions 408, 410. Optionally, the edges or inclined surfaces 428 can also be configured to seal off the reaction space 406.

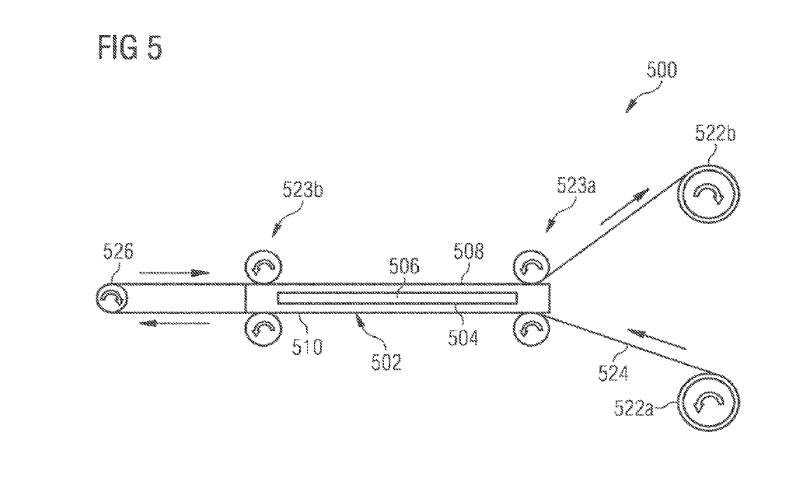

The embodiment shown in FIG. 5 of a device 500 for coating substrates includes a reaction space element, for example in the form of a frame 502, which is arranged between two opposite substrate portions 508, 510. A material feed element, for example in the form of an inlet nozzle 504, is formed in one side of the frame 502.

By the frame 502, the substrate portions 508, 510 may be arranged as mutually opposite outer walls of the reaction space 506. Motorized rollers 522a, b guide a film 524, in each case at an angle, to and from a pair of rolls 523a. A further pair of rolls 523b is arranged at the other end of the frame 502. The pairs of rolls 523a, 523b can advantageously press the film 524 onto the frame 502 in order to seal off the reaction space 506.

In this embodiment, the device 500 may have a material removal element, for example in the form of an outlet nozzle in the side of the frame 502 that is opposite the inlet nozzle 504.

A deflection roll 526 deflects the film 524 on one side of the frame 502.

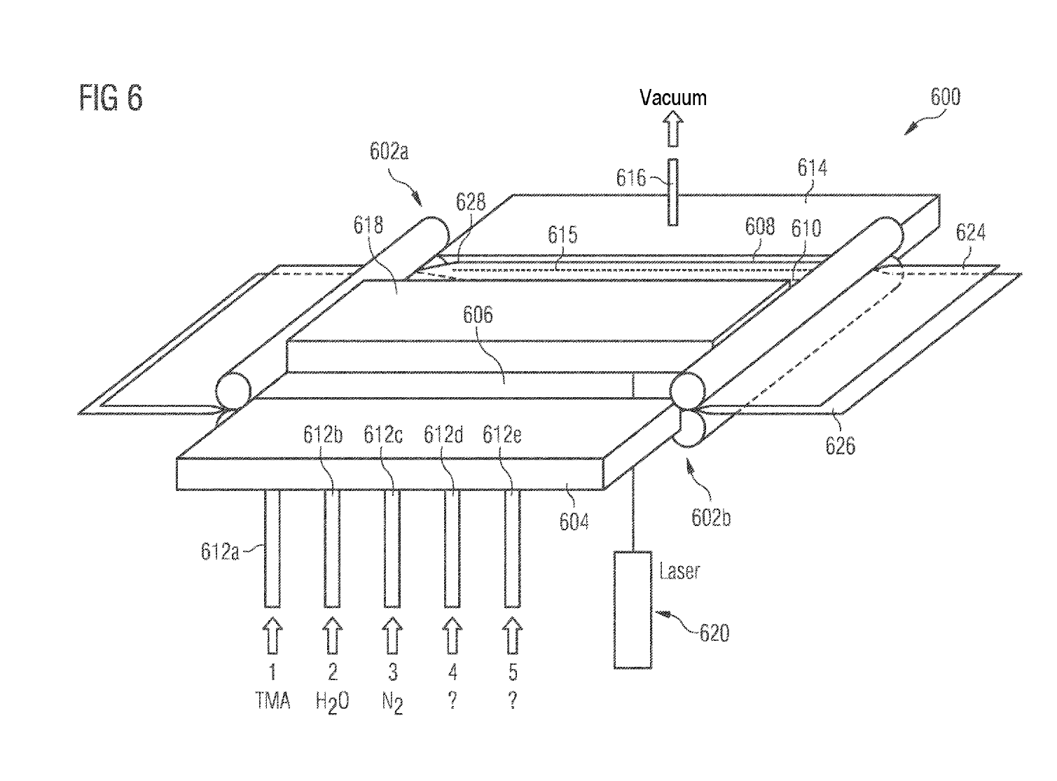

The embodiment shown in FIG. 6 of a device 600 for coating substrates includes a reaction space element, for example in the form of two pairs of rolls 602a, 602b, and a material feed element, for example in the form of a nozzle 604. The nozzle 604 has a slot directed into a reaction space 606 between mutually opposite substrate portions 608, 610. Various feed lines, e.g. 612a to 612e, are coupled to the nozzle 604 in order to introduce one or more materials, for example one or more precursors and one or more carrier gases for coating the substrates, into the reaction space 606.

By the pairs of rolls 602a, 602b, the substrate portions 608, 610 may be arranged as mutually opposite outer walls of the reaction space 606. Motorized rollers (not shown) guide films 624, 626, each at an angle, to and from the pairs of rolls 602a, 602b. The pairs of rolls 602a, 602b can advantageously press the films 624, 626 against one another in order to seal off the reaction space 606.

In this embodiment, the device 600 may include a material removal element, for example in the form of a second nozzle 614. The second nozzle 614 has a slot 615 directed toward the reaction space 606 in order to extract the materials by vacuum. A vacuum line 616 leading to a vacuum pump (not shown) is coupled to the second nozzle 614 for this purpose.

In this embodiment, the reaction space element may also include guide elements formed on the nozzle 604 and/or the second nozzle 614, e.g. in the form of edges or inclined surfaces 628 for the substrate portions 608, 610. Optionally, the edges or inclined surfaces 628 may also be configured to form seals for the reaction space 606.

In this embodiment, the device 600 may additionally include a component 618 above the substrate portion 608. The component 618 can be, for example, in the form of one or more elements of a group including an exposure unit (for example a reflector and tube lamps and/or a light-emitting diode (LED) array), heating (for example an array of ceramic emitters (e.g. from Elstein), infrared (IR) lamps and reflector, heating mat), plate with coupled ultrasound generator, electrode for generating a (dielectric barrier) discharge in the reaction space 606, e.g. plasma, and laser for structuring.

In this embodiment, the device 600 may additionally include a component underneath the substrate portion 610, here in the form of a laser 620. The component underneath the substrate portion 610 in other embodiments may be in the form of one or more elements of a group including an exposure unit (for example a reflector and tube lamps and/or a light-emitting diode (LED) array), heating (for example an array of ceramic emitters (e.g. from Elstein), infrared (IR) lamps and reflector, heating mat), plate with coupled ultrasound generator, electrode for generating a (dielectric barrier) discharge in the reaction space 606, e.g. plasma, and laser for structuring. In the embodiments described, the substrates may advantageously be accessible for additional supporting processes, for example heating (e.g. by infrared (IR) radiation), exposure (e.g. by ultraviolet (UV) radiation), vibration (e.g. by ultrasound) or else structuring (e.g. by laser).

Outside the reaction space, electrodes may also be attached to the substrates in order to generate plasmas in the reaction space. Alternatively, the inlet and outlet nozzles may also be used as electrodes, or electrodes which project into the reaction space can be attached.

By these options, in diverse embodiments, both thermal and photo-induced and plasma-induced ALD/MLD processes can advantageously be carried out.

In the embodiments described, the substrates, e.g. in the form of films, may be moved either continuously or cyclically, so that roll-to-roll (R2R) operation is advantageously easily possible.

In addition, the structure in the embodiments described may make it possible for maintenance (e.g. cleaning of reaction spaces) after specific operating times to be substantially simplified. It is then advantageously necessary only for the nozzles and any lateral sealing elements that may be present to be cleaned or replaced by others. If, for example, the extraction nozzle is omitted, only the inlet nozzle needs to be cleaned or replaced by another. As a result, it is advantageously possible to arrive at only a short or virtually no production stoppage.

In the embodiments described, when the spacer elements are used, ALD/MLD processes at pressures below the ambient pressure are, moreover, possible.

In further embodiments, the structure may be combined with a following laminating apparatus, e.g. in order to produce an opto-electronic component that is encapsulated and provided with a protective film.

In addition, in further embodiments, a plurality of units according to the embodiments described above can be combined, e.g. arranged one above another or one after another.

In an embodiment, a plurality of reaction space elements with a common material feed element (and, optionally, a common material removal element) may be used. In a further embodiment, a plurality of material feed elements (and, optionally, a plurality of material removal elements) may be used in order to introduce the materials for coating the substrates into the respective reaction spaces.

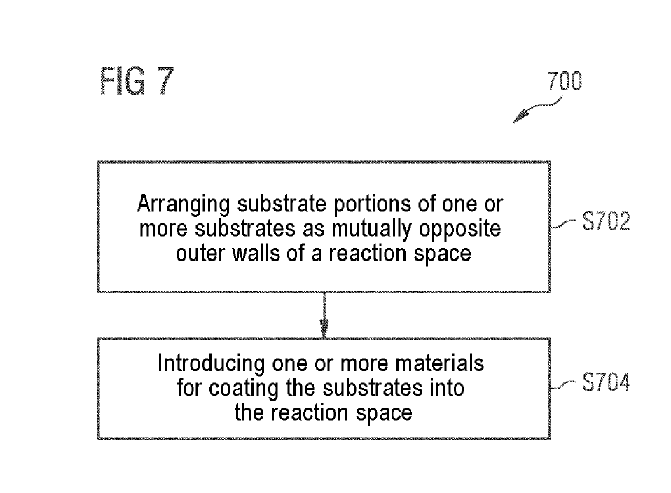

FIG. 7 shows a flow chart 700 of an embodiment of a method for coating substrates. In S702, mutually opposite substrate portions of one or more substrates are arranged as respective outer walls of a reaction space. In S704, one or more materials is or are introduced into the reaction space to coat the substrates.

The embodiments described can advantageously have one or more of the following effects:
the reaction space is formed substantially only between the two mutually opposite portions of the substrates;
an economical method/an economical device for producing thin layers, for example on flexible substrates, by ALD or MLD processes with high material utilization and short process times;
a simple structure;
the cleaning necessary at specific intervals may be less complicated as compared with conventional systems;
the method/the device is suitable for roll-to-roll (R2R) production;
high material utilization as a result of virtually complete formation of the reaction space from substrate surfaces (less undesired coating at other points);
low gas and precursor consumption as a result of low process volume and easily estimated metering (unnecessarily high overdosing of the precursors may advantageously be avoided);
short cycle times as a result of low volume and advantageous flow characteristics (faster gas exchange) can permit high growth rates: e.g. approximately 50 ms/partial step, i.e. approximately 200 ms/cycle (4 partial steps), that is to say approximately 300 cycles/min. Given a layer growth of approximately 0.1 nm/cycle, the result is then a growth rate of approximately 30 nm/min;
suitable for R2R mass production: e.g. the result for approximately 30 cm wide substrates and approximately 50 cm long portions is an area per substrate portion of 0.3 m×0.5 m=0.15 m², therefore a total area of 0.15 m²×2 (top and bottom)=0.3 m², so that 0.3 m² per minute can be coated with approximately 30 nm (corresponds to approximately 18 m²/h);
as a result of accessibility of the substrates, heating, exposure etc. can be implemented simply as process-assisting or -inducing measures. In addition, structuring, e.g. by means of lasers, is possible;
simple and economical structure, above all as compared with R2R spatial ALD, simple maintenance;
as compared with spatial ALD, more simply expandable to additional material systems (e.g. ternary compounds, arbitrarily alternating layer sequences etc.). Problems of the spatial ALD variants with regard to contact of the substrates with coating heads advantageously do not occur;
on at least one of the substrates there can already be an electronic component structure (e.g. opto-electronic stack) from a preceding step, which is to be provided with an encapsulating layer (barrier against water and oxygen) and then laminated together with an additional barrier film as protection. This is not complex in the case of the structure according to diverse embodiments, since the two substrates (e.g. one substrate with stack, one substrate without stack) can be fed in above one another;
low space requirement with numerous units arranged one above another.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A device for coating substrates, comprising:
a reaction space element configured to arrange substrate portions of one or more substrates as opposite outer walls of a reaction space; and
a material feed element configured to introduce one or more materials into the reaction space for coating surfaces of the substrate portions which are opposite one another in the reaction space.

2. The device as claimed in claim 1,
wherein the reaction space element is configured for the continuous or cyclic movement of the substrate portions.

3. The device as claimed in claim 1,
wherein the reaction space element includes at least two rolls, wherein the reaction space is arranged between the two rolls.

4. The device as claimed in claim 1,
wherein the reaction space element includes at least two pairs of rolls,
wherein the reaction space is arranged between the two pairs of rolls.

5. The device as claimed in claim 1,
wherein the material feed element is arranged laterally along the reaction space.

6. The device as claimed in claim 1,
wherein the reaction space element includes a frame element, wherein the reaction space is arranged within the frame element.

7. The device as claimed in claim 6,
wherein the material feed element is arranged on one side of the frame element.

8. The device as claimed in claim 6,
wherein the material feed element forms one side of the frame element.

9. The device as claimed in claim 1, further comprising:
a material removal element which is configured to extract the one or more materials out of the reaction space by vacuum.

10. The device as claimed in claim 1,
wherein the reaction space element includes one or more guide elements formed on the material feed element.

11. The device as claimed in claim 1, further comprising:
one or more electrodes, which are configured to generate a plasma in the reaction space.

12. The device as claimed in claim 1, further comprising:
a spacer element which is configured to set a distance between the substrate portions in the area of the reaction space.

13. The device as claimed in claim 12,
wherein the spacer element includes a vacuum element.

14. The device as claimed in claim 12,
wherein the spacer element includes at least two vacuum elements arranged on opposite sides of the substrate portions.

15. The device as claimed in claim 1,
wherein the device has a plurality or a multiplicity of reaction space elements.

16. The device as claimed in claim 1,
wherein the device has a plurality or a multiplicity of material feed elements.

17. A method for coating substrates, the method comprising:
arranging substrate portions of one or more substrates as mutually opposite outer walls of a reaction space; and
introducing one or more materials into the reaction space for coating surfaces of the substrate portions which are opposite one another in the reaction space.

18. The method as claimed in claim 17, further comprising:
moving continuously or cyclically the substrate portions.

19. The method as claimed in claim 17, further comprising:
extracting the one or more materials out of the reaction space by vacuum.

20. The method as claimed in claim 17, further comprising:
generating a plasma in the reaction space.

21. The method as claimed in claim 17, further comprising:
setting a distance between the substrate portions in the area of the reaction space.

22. The method as claimed in claim 17, further comprising:
one or more processes from a group comprising heating, exposing, vibrating, laminating and structuring the substrate portions.
